(19) United States
(12) Patent Application Publication
(10) Pub. No.: US 2003/0030086 A1
(43) Pub. Date: Feb. 13, 2003

(54) DRAM circuitry with a longer refresh period

(76) Inventors: Ta-Cheng Lin, Hsin-Chu City (TW); Jui-Lung Chen, Hsin-Chu City (TW); Shih-Huang Huang, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/682,214

(22) Filed: Aug. 7, 2001

(51) Int. Cl. H01L 27/108

(52) U.S. Cl. 257/296

(57) ABSTRACT

A DRAM circuitry includes a DRAM cell that is connected at a first end to a bit line, at a second end to a plate line, and at a third end to a word line, and a sensing amplifier that is electrically connected to the DRAM cell for refreshing the DRAM cell and reading data from the DRAM cell. The sensing amplifier can change a potential of the bit line and a potential of the plate line to write data into the DRAM cell when the word line is turned on.

### BACKGROUND OF INVENTION

1. Field of the Invention

The present invention relates to DRAM circuitries, and more particularly, to a DRAM circuitry with a longer refresh period.

2. Description of the Prior Art

Dynamic random access memory (DRAM) is a form of memory commonly found in computers and many handheld devices. As suggested by its name, DRAM is medium that can changeably store information. A chip of DRAM typically has a multitude of DRAM cells, all of which can be electrically written to and read from multiple times.

Please refer to FIG. 1, which is a circuit schematic diagram of a prior art DRAM circuitry 10 in MOS technology. The DRAM 10 comprises a plurality of DRAM cells 20, a bit line isolation circuit 30, and a sensing amplifier 40. Each DRAM cell 20 comprises a MOS transistor 21 connected with a capacitor 22. A drain 23 of each transistor 21 is connected to either a bit line (BL) 26 or a bit line bar (BLB) 27. A plurality of word lines (WL) 28 connect to corresponding gates 24 of each transistor 21. A source 25 of each transistor 21 is connected to the capacitor 22 of the same DRAM cell 20. Each capacitor 22 connects to a plate line (PL) 29. The bit line isolation circuit 30 is simply a gate-to-gate connected pair of transistors 31 separating the sensing amplifier 40 from the plurality of DRAM cells 20. The sensing amplifier 40 is well documented and, therefore, not described in detail. However, please note that a voltage equalizer V_{EQ} equalizes voltage across BL 26 and BLB 27 before data stored in DRAM cells are read, and determines plate voltage V_{PL} to be ½V_{CC}, one half of supply voltage.

From a basic knowledge of circuits, the capacitors 22 of the DRAM cells 20 act as memory storage elements in the DRAM. Capacitors are not perfect memory storage elements, i.e. voltage across capacitors decays with time. So, it is necessary to periodically refresh data stored across the capacitor. Under normal circuit operation, the plate voltage V_{PL} is set at one half of the supply voltage V_{CC}/2. If the gate 24 of the transistor 21 is held to V_{CC}, the highest voltage appearing at the capacitor 22 is (V_{CC}/2)−V_{GS}. This leaves a very small potential difference across the capacitor 22 from the drain 23 of the transistor 21 to the plate line 29. To illustrate this, assume that V_{CC} is 3.3V, and V_{GS} is 0.7V. This leaves an initial voltage across the capacitor 22 of only 0.95V. Even without decay, this voltage is nearly mistakable as logic 0 (assuming positive logic). To compound the issue, the existence of the bit line isolation circuit 30 further drops another V_{GS} of voltage at each of the BL 26 and BLB 27.

To improve V_{BL} and V_{BLB}, a charge pump circuit can be inserted to recover the V_{GS} drop occurring at BL 26 and BLB 27. Additionally, charge pumps may be added to the transistors 21 to compensate for the V_{GS} drop occurring before data reaches the capacitor 22. However, these methods are only surface level fixes, which do not significantly raise the voltage stored at the capacitors 22. Specifically, taking the same circuit values mentioned above, adding charge pumps to compensate for the V_{GS} drop due to the bit line isolation circuit 30, and the V_{GS} drop occurring at the DRAM cell 20, would give an initial voltage across the capacitor 22 of only 1.65V. Furthermore, two charge pumps have now been added to the circuit, which is inconvenient and expensive. And, the circuit still must be refreshed very often to avoid data loss.

### SUMMARY OF THE INVENTION

It is therefore an objective of the present invention to provide DRAM circuitry that has an improved refresh rate.

Briefly, the claimed invention provides a DRAM circuitry comprising a DRAM cell that is connected at a first end to a bit line, and at a second end to a plate line, and a sensing amplifier that is electrically connected to the DRAM cell for refreshing the DRAM cell and reading data from the DRAM cell. The sensing amplifier can change plate line and bit line voltages in order to write data into the DRAM cell.

It is an advantage of the claimed invention that a voltage across a capacitor of the DRAM cell approaches a supply voltage of the DRAM circuitry, which allows the DRAM circuitry to delay longer before performing a refresh operation.

These and other objectives of the present invention will no doubt become obvious to those of ordinary skill in the art after reading the following detailed description of the preferred embodiment which is illustrated in the various figures and drawings.

### BRIEF DESCRIPTION OF DRAWINGS

FIG. 1 is a circuit schematic diagram of DRAM circuitry according to the prior art.

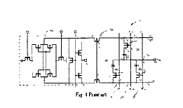

FIG. 2 is a circuit schematic diagram of DRAM circuitry according to the present invention.

### DETAILED DESCRIPTION

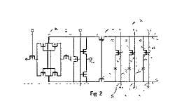

Please refer to FIG. 2, which is a circuit schematic diagram of a DRAM circuitry 50 according to the present invention. The DRAM circuitry 50 comprises a plurality of DRAM cells 60, a sensing amplifier 80, and a bit line isolator 70 that isolates the DRAM cells 60 from the sensing amplifier 80. Each DRAM cell 60 comprises a transistor 61 and a capacitor 62 that is connected to a source 65 of the transistor 61. A second end of the capacitor 62 is connected to a plate line (PL) 51. A drain 63 of each transistor 61 is connected to a bit line (BL) 52. A gate 64 of each transistor 61 is connected to one of a plurality of word lines (WL) 53. The sensing amplifier 80 is a well-known device and is not described in detail here. Please note that a voltage equalizer V_{EQ} equalizes voltage across BL 52 and PL 51 before data stored in DRAM cells 60 are read.

In order to increase a delay needed before refreshing data in the plurality of DRAM cells 60, a voltage across the capacitors 62 must also increase. To accomplish this, the plate line 51 is disconnected from the voltage equalizer V_{EQ} and is therefore floated, and BL 52 can have a relative voltage up to a difference between supply voltage and a gate-source voltage of a transistor 71 of the bit line isolator 70, i.e. V_{CC}−V_{GS}. Taking the above-mentioned values of V_{CC} as 3.3V and V_{GS} as 0.7V, the voltage difference across the capacitor 62 during a write operation is 2.6V. Compared to the prior art best case, with two charge pumps, this is a 0.95V increase. Of course, adding charge pumps to the present invention DRAM circuitry 50 is totally acceptable, and can be used to increase the voltage across the capacitor 62 to the full 3.3V. A result of this much higher stored voltage is that a time needed for data on the capacitor 62 to decay to a state of being useless is increased significantly, thereby allowing for much less periodic refresh rates. Indirectly, other circuit parameters can potentially be changed to take advantage of this lower refresh rate, including lower source power requirements, as well as removing a need for charge pump circuitry.

In contrast with the prior art, the present invention DRAM circuitry has DRAM cells that are connected across almost an entire supply voltage. As a result, the DRAM circuitry can be refreshed less often, which saves power and clock cycles. In addition, having such a high potential difference between the bit line and the plate line of the present invention removes the need for charge pump circuitry, reducing the overall power consumption and cost of the DRAM circuitry.

Those skilled in the art will readily observe that numerous modifications and alterations of the device may be made while retaining the teachings of the invention. Accordingly, the above disclosure should be construed as limited only by the metes and bounds of the appended claims.

What is claimed is:

1. Dynamic random access memory (DRAM) circuitry comprising:
a DRAM cell having a first end connected to a bit line and a second end connected to a plate line; and
a sensing amplifier electrically connected to the DRAM cell for refreshing the DRAM cell and reading data from the DRAM cell;
wherein the sensing amplifier is capable of changing a potential of the bit line and a potential of the plate line to write data into the DRAM cell.

2. The DRAM circuitry of claim 1 wherein the plate line is floating because the plate line is disconnected from a power supply.

3. The DRAM circuitry of claim 2 further comprising a voltage equalizer electrically connected to both the bit line and the plate line for equalizing the potential of the bit line and the potential of the plate line before reading the data within the DRAM cell.

4. The DRAM circuitry of claim 1 further comprising a bit line isolation for isolating different bit lines and limiting voltages of the bit lines.

5. The DRAM circuitry of claim 1 wherein the DRAM cell further comprises a third end connected to a word line, and the word line is turned on when the DRAM cell is to be refreshed or the data within the DRAM cell is to be read.

6. The DRAM circuitry of claim 5 wherein the DRAM cell comprises a transistor and a capacitor, the third end of the DRAM cell is a gate of the transistor.

7. Dynamic random access memory (DRAM) circuitry comprising:
a plurality of DRAM cells each having a first end connected to a bit line, a second end connected to a plate line and a third end connected to a word line;
a sensing amplifier electrically connected to the DRAM cell for refreshing the DRAM cell and reading data from the DRAM cell; and
a bit line isolation for isolating different bit lines and limiting voltages of the bit lines;
wherein the sensing amplifier is capable of changing a potential of the bit line and a potential of the plate line to write data into the DRAM cell.
